(19) United States
(12) Patent Application Publication
(10) Pub. No.: US 2015/0013767 A1
(43) Pub. Date: Jan. 15, 2015

(54) FLOATING ANCHOR CURB MODULE

(71) Applicant: Barak Yekutiely, Kochav Yair (IL)

(72) Inventor: Barak Yekutiely, Kochav Yair (IL)

(21) Appl. No.: 13/938,242

(22) Filed: Jul. 10, 2013

(51) Int. Cl. H01L 31/042

(52) U.S. Cl. CPC H01L 31/0422
USPC 136/259

(57) ABSTRACT

A floating anchor curb includes a frame and a wrap member wrapped around the frame. The frame has an inner ballast volume partially filled with water. A tensioning element is disposed in or on the frame, and is arranged to apply tension on the wrap member.

### FIELD OF THE INVENTION

The present invention relates generally to floating cover systems, and particularly to a floating anchor curb module for use with floating cover systems and/or photovoltaic and solar energy systems.

### BACKGROUND OF THE INVENTION

Traditional photovoltaic systems are designed to be installed on the ground, for example agricultural grounds, or roofs and other fixed arrangements on flat or tilted surfaces. However, installation of these systems has disadvantages, both environmental ones and safety ones, as in the case of laying large, heavy, and wind prone systems on building roofs that may also damage the building roof structure. In addition, the systems are limited by laws that wish to minimize the environmental impact for preservation of the landscape, or which maximize the land occupation for farming or for other types of exploitation.

Accordingly, floating solar panel installations have been developed, such as for the sea, river, lake, lagoon surfaces, and artificial basins. These systems are based on photovoltaic floating systems. However, it is not easy to finance and build large floating structures for such systems that need to meet both project budget constraints as well as long-term performance requirements under extreme environmental conditions.

US Patent Application 2008/0029148 describes a floating structure for the support of solar panels. The structure includes rows of extended tubular elements that support photovoltaic panels arranged with an appropriate slope in order to get the higher absorption of solar rays.

However, structures of this type have disadvantages, such as assembly, maintenance difficulties and high cost.

PCT Patent Application WO 2010064271 describes a modular floating structure for photovoltaic installations. The system has raft-like floating elements which can be inter-connected in such a way to obtain uniform floating surfaces able to hold the supporting structures of the photovoltaic panels and to form a continuous surface for the passage of the maintenance staff. The supporting structures can tilt the panels in an optimal tilted position for the absorption of solar rays.

US Patent Application 20120279557 describes a floating support structure for solar panels and/or concentration collectors. The system mounts an array of solar panels or other PV or thermal elements on modular floating platforms joined together to form an array. The system has provisions for assembling and connecting floating support modules on land for deployment onto water using a crane or roller conveyor system. There is also a mooring and anchoring system for connecting the array to shore in a manner that prevents overstress of the structural components comprising the array field.

### SUMMARY OF THE INVENTION

The present invention seeks to provide a floating anchor curb module for water reservoirs, as is explained more in detail hereinbelow.

There is provided in accordance with an embodiment of the invention a floating anchor curb module including a frame and a wrap member wrapped around the frame, the frame having an inner ballast volume partially filled with water, and a tensioning element disposed in or on the frame, which is arranged to apply tension on the wrap member.

### BRIEF DESCRIPTION OF THE DRAWINGS

The present invention will be understood and appreciated more fully from the following detailed description taken in conjunction with the drawing in which:

FIG. 1 is a simplified illustration of a floating anchor curb module, constructed and operative in accordance with a non-limiting embodiment of the present invention.

### DETAILED DESCRIPTION OF EMBODIMENTS

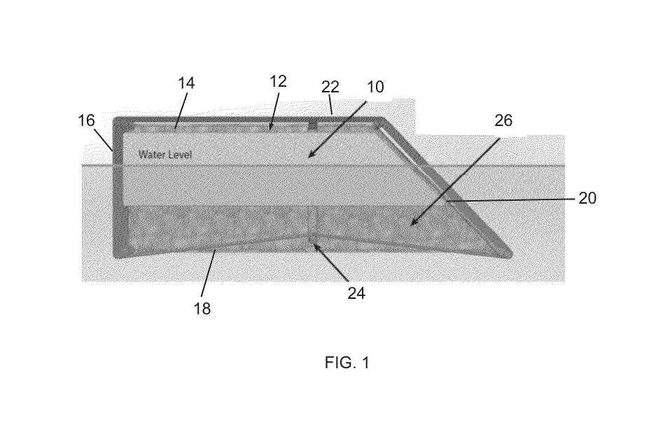

Reference is now made to FIG. 1, which illustrates a floating anchor curb module 10, constructed and operative in accordance with a non-limiting embodiment of the present invention.

Floating anchor curb module 10 includes a frame 12, which may be of any size or shape. In a preferred embodiment, as shown in the figure, frame 12 has a generally flat planar top (horizontal) surface 14, three generally flat planar side (vertical) surfaces 16, a generally flat planar bottom (horizontal) surface 18, and an inclined side surface 20. (This forms a trapezoidal cross-sectional shape.) A wrap member 22 is wrapped around frame 12; that is, it is wrapped around top surface 14, at least one of the side surfaces 16, bottom surface 18 and inclined surface 20. Wrap member 22 may be any kind of geomembrane roll, band, wrap and the like.

The tension of wrap member 22 is determined by a tensioning element 24 disposed in or on frame 12. For example, tensioning element 24 may be mounted on the inner side of bottom surface 18 (a portion of wrap member 22 thus goes inside the frame 12 in such a case). Tensioning element 24 may be a telescoping mechanism, ratcheting mechanism, a screw mechanism, worm gear mechanism, and the like, and may be manually controlled or remotely controlled, such as by a servomotor which adjusts the tensioning, and which may operate in a closed-loop servo-system with sensors that sense the operating conditions and adjust the tensioning accordingly.

The size of the wrap member 22 around frame 12 determines the total ballast volume. The tension of wrap member 22 on frame 12 by the tensioning element 24 determines the fluid flow rate (both of air and water) in and out of an inner volume of module 10. This inner volume is referred to as the ballast volume 26. It is partially filled with water to form the ballast weight. The tension of the wrap member 22 dynamically changes the walls of the floating anchor curb module 10 from very taut with a small leakage rate to very loose with a large leakage rate. The wrap member may press against a gasket that helps seal against leakage; when very taut, there is no leakage, but there is progressively more leakage as the wrap member is loosened. This provides a unique ballast functionality of a floating anchor curb module 10.

In addition, the invention enables using very low density and low cost foam as the material for the floating frame 12, which presses on the underside of the tensioned wrap member 22. (Of course, other materials can be used as well, such as metal, plastic or wood.) The cover wrap member 22 can be seamed directly to the top side of the floating anchor curb module 10. Indeed, a person can walk the top side of the floating anchor curb module 10.

The invention has application not only in fresh water or drinking water installations, but also can be used as a floating dock for many applications including floating photovoltaic systems, where water is not a scarce resource, such salty water or sewage water. The invention can be used in conjunction with photovoltaic panels to create a WIPV (Water Integrated Photovoltaic) system, that is, a photovoltaic covering for a body of water that solar generates electrical power for various applications, as is described in PCT Patent Application PCT/IL2007/000567.

What is claimed is:

1. Apparatus comprising:
a floating anchor curb module comprising a frame and a wrap member wrapped around said frame, said frame having an inner ballast volume partially filled with water; and
a tensioning element disposed in or on said frame, which is arranged to apply tension on said wrap member.

2. The apparatus according to claim 1, wherein a size of said wrap member around said frame determines the total ballast volume and tension of said wrap member on said frame by said tensioning element determines a fluid flow rate in and out of said floating anchor curb module.

3. The apparatus according to claim 1, wherein a tension of said wrap member dynamically changes walls of said floating anchor curb module from very taught with a small leakage rate to very loose with a large leakage rate.

4. The apparatus according to claim 1, wherein said frame comprises a generally flat planar top surface, three generally flat planar side surfaces, a generally flat planar bottom surface, and an inclined side surface.

5. The apparatus according to claim 4, wherein said wrap member is wrapped around said top surface, at least one of said side surfaces, said bottom surface and said inclined surface.

6. The apparatus according to claim 1, wherein a portion of said wrap member is inside said frame.

7. The apparatus according to claim 1, wherein said wrap member comprises a geomembrane.

8. The apparatus according to claim 1, wherein said tensioning element is mounted on an inner side of said frame.
